(19) United States
(12) Patent Application Publication
(10) Pub. No.: US 2010/0219267 A1
(43) Pub. Date: Sep. 2, 2010

(54) SPRAY NOZZLE

(75) Inventor: Yiton Fu, Sharnbrook (GB)

Correspondence Address: UNILEVER PATENT GROUP, 800 SYLVAN AVENUE, AG West S. Wing, ENGLEWOOD CLIFFS, NJ, 07632-3100, US

(73) Assignee: CONOPCO, INC., D/B/A UNILEVER, Englewood Cliffs, NJ (US)

(21) Appl. No.: 12/711,483

(22) Filed: Feb. 24, 2010

(30) Foreign Application Priority Data
Feb. 27, 2009 (EP) EP09153960

(51) Int. Cl. A62C 31/02; G03F 7/20

(52) U.S. Cl. 239/589; 430/320

(57) ABSTRACT

The invention relates to a nozzle for producing a spray, a method for their manufacture and a dispenser incorporating the inventive nozzle. It is contemplated that the inventive nozzle is used in dispensers for deodorant sprays.

Nozzles for deodorant spray dispensers have a single large (typically 500 microns in diameter) aperture and, when in use, require a volatile liquid to atomise the deodorant. There is little control over the size and shape of spray cone produced by such dispensers and thus limited prospects for controlling the same.

The invention provides a nozzle for producing a spray, the nozzle comprising a tube and a film, the film being affixed to the tube and covering the bore, wherein the film comprises a plurality of apertures through which a fluid may pass from inside of the tube, and wherein the film comprises a plurality of layers of exposed dry film photoresist.

This invention relates to a nozzle for producing a spray, a method for its manufacture and a dispenser incorporating the inventive nozzle. The inventive nozzle can be used in dispensers for deodorant sprays or in drug delivery devices such as inhalers.

Nozzles for deodorant spray dispensers have a single large (typically 500 microns in diameter) aperture and, when in use, require a volatile liquid to atomise the deodorant. There is little control over the size and shape of spray cone produced by such dispensers and thus limited prospects for controlling the same.

Nozzles used for inhalers (such as those available from Medspray) have much smaller apertures (typically one dimension which is only a few microns) and comprise a plastics or metal tube, a perforated wafer of silicon coated with either silicon dioxide or silicon nitride, the perforated wafer being affixed by adhesive over one end of the plastics tube, and a metal or plastics annular clip for further securing the perforated wafer onto the plastics tube. The perforated laminated wafer is prepared by coating the silicon dioxide or silicon nitride with a photoresist and exposing the coating to either ultra-violet radiation or an electron beam thereby to produce a plurality of apertures in the photoresist coating. The photoresist coating is then used as a mask in combination with reactive ion etching to produce an identical pattern of apertures in the silicon dioxide or silicon nitride. The silicon is then removed, either through wet chemical etching or reactive ion etching, from beneath the apertures thereby to leave supporting rings of silicon around the apertures. One disadvantage of this method of producing nozzles is that production of the perforated wafer requires a large amount of specialised equipment. Another disadvantage is the inherent incompatibility of the perforated wafer and the plastics or metal tube which requires use of an adhesive to join the two parts together. This joining operation is itself also difficult to achieve as a high degree of precision is required to prevent overflow of the adhesive. Yet a further disadvantage of this method is the need for a metal or plastics annular clip for further securing the perforated wafer onto the plastics tube.

In an alternative embodiment, a perforated metal foil in used in place of the aforementioned perforated wafer. The perforations in the metal foil are produced with a laser. This embodiment suffers the same disadvantages as the perforated wafer with the exception of the need for clean conditions.

### SUMMARY OF THE INVENTION

In a first aspect of the invention, a nozzle for producing a spray is provided, the nozzle comprising a tube and a film, the film being affixed to the tube and covering the bore, wherein the film comprises a plurality of apertures through which a fluid may pass from inside of the tube, and wherein the film comprises a plurality of layers of exposed dry film photoresist.

By the term “exposed dry film phororesist” is meant dry film photoresist which has been exposed to heat, ultra-violet radiation or an electron beam.

A particular advantage of a film comprising a plurality of layers of dry film photoresist is the flexibility that such a film gives to defining the shape of the apertures. Thus the shape may vary through the film by simply changing the aperture size in each of the layers of dry film photoresist as they are laid down. This particularly allows for shapes which cannot be obtained by drilling such as:
apertures with narrow cross section at each end and large cross section in the middle
apertures with very high aspect ratio (high length/small diameter). Apertures with an aspect ratio of over 10 and even or 15 have been produced according to the invention).

This flexibility is not available with a liquid phororesist which is spun coated onto a surface because each new layer of liquid photoresist would fill in the apertures of the preceding layer of “cured” photoresist.

The film is typically 10-400, preferably 10-200, more preferably 10-100, even more preferably 10-50 microns in thickness.

Preferably the tube comprises a plastics material, examples of which include acrylonitrile butadiene styrene, polymethyl methacrylate, celluloid, cellulose acetate, ethylene vinyl acetate, ethylene vinyl alcohol, fluoroplastics, ionomers, acrylic-polyvinyl chloride alloy trade marked as Kydex™, polyacetal, polyacrylates, polyacrylonitrile, polyamide, polyamide-imide, polyaryletherketone, polybutadiene, polybutylene, polybutylene terephthalate, polycaprolactone, polychlorotrifluoroethylene, polyethylene terephthalate, polycyclohexylene dimethylene terephthalate, polycarbonate, polyhydroxyalkanoates, polyketone, polyester, polyethylene, polyetherketoneketone, polyetherimide, polyethersulfone, polyethylenechlorinates, polyimide, polylactic acid, polymethylpentene, polyphenylene oxide, polyphenylene sulphide, polyphthalamide, polypropylene, polystyrene, polysulfone, polytrimethylene terephthalate, polyurethane, polyvinyl acetate, polyvinyl chloride, polyvinylidene chloride and styrene acrylonitrile. An advantage of using a plastics tube is the increased scope for improving the joint between the tube and the film as both parts are then comprised of plastics. Thus preferably the film is welded to the tube. Furthermore the film may be welded to the tube by laser welding or ultrasonic welding. Ultrasonic welding requires both the tube and film to comprise thermoplastics in order to effect a joint.

The dry film photoresist is preferably a negative photoresist, preferably based on an acrylic or epoxy polymer. An example of a suitable negative dry film photoresist is Tokyo Ohka Kogyo Company Limited TOK 940 which is an acrylic based dry film photoresist with a film thickness of 40 microns.

The film preferably comprises 2-10, preferably 3-8, most preferably 4-6 layers of exposed dry film photoresist.

Preferably the apertures have a shortest surface dimension no greater than 20 microns, preferably no greater than 30 microns, most preferably no greater than 50 microns. By the term “shortest surface dimension” in relation to an aperture is meant the dimension which is the largest and is measured on the surface of the film and thus this excludes the depth of the aperture through the film. The advantage of an aperture with a shortest surface dimension no greater than 20 microns, preferably no greater than 30 microns, most preferably no greater than 50 microns is that when the inventive nozzle is in use, a volatile liquid is not required to atomise any product to be dispensed through the inventive nozzle. Preferably each aperture has a shortest surface dimension of 5-305, more preferably 10-25 microns.

Preferably each aperture has a spacing of at least ten times the shortest surface dimension of each aperture thereby to prevent interference between any product being dispensed from each aperture leading to a breakdown in the shape and quality of the spray cone.

In a second aspect of the invention, a dispenser is provided, the dispenser comprising a can which can be pressurised, a valve for regulating the passage of any can contents from the can interior to the can exterior, and a nozzle in accordance with any one of the preceding claims, wherein the can comprises a can aperture, and the nozzle is arranged to cooperate with the can aperture such that any can contents passing from the can interior to the can exterior pass through the nozzle.

Preferably the dispenser is pressurised by a propellant which is not a volatile organic compound. By the term “volatile organic compound” is meant an organic compound with a boiling point at or slightly below room temperature (23 degrees centigrade). The advantage of not using a volatile organic compound as propellant is that the dispenser has a lower environmental impact when in use. As volatile organic compounds are often flammable, a further advantage is that the dispenser is safer to use.

Preferably the dispenser is pressurised by a propellant which is not soluble in the product to be dispensed from the dispenser. The advantage of this is that the product will not then be atomised into an aerosol of droplet size small enough to be inhaled by a consumer. For products such as personal care products, for example, deodorants and/or antiperspirants, inhalation of product droplets by the consumer is not desirable. Thus preferred propellants for personal care products are nitrogen or carbon dioxide. Preferably the majority of the droplets have a droplet size greater than or equal to 20 microns.

The can may be pressurised with propellant at 1-10 bar. Preferably the dispenser is pressurised with propellant at 1.1-7, more preferably 1.1-5 bar.

In a third aspect of the invention, a method of manufacturing a nozzle according to the first aspect is provided, the method comprising in the following order the steps of:
(a) Providing a dry film photoresist;
(b) Laminating the dry film photoresist to a substrate thereby to produce a laminated dry film photoresist;
(c) Selectively exposing parts of the dry film photoresist to ultra-violet radiation or an electron beam thereby to produce exposed dry film photoresist;
(d) Removing that part of the exposed dry film photoresist which is less chemically robust; and either
(e) Delaminating the substrate thereby to produce the film; and then affixing the film to the tube; or
affixing the laminated and exposed dry film photoresist to the tube; and then delaminating the substrate thereby to produce the film now affixed to the tube

Step (b) is typically carried out by laminating the dry film photoresist to a polystyrene substrate.

Step (d) is preferably accomplished with a developer. A developer suitable for an acrylic negative dry film photoresist is an aqueous solution of hydrated sodium carbonate.

The inventive method preferably comprises the additional step (f) between steps (d) and (e) of hardening the exposed dry film photoresist using heat, ultra violet light or an electron beam. Step (f) permits further chemical reaction within the film to take place following step (e) which was not possible before step (e) due to the risk that the ultra-violet radiation or electron beam is exposed or excessively exposed to that part of the dry film photoresist intended for removal in step (e).

The inventive method may also comprise the additional steps between steps (d) and (e) and after the optional step (f) of:
(g) Laminating a further layer of dry film photoresist to the exposed dry film photoresist; then
(h) Selectively exposing parts of the further layer of dry film photoresist to ultra-violet radiation or an electron beam; then
(i) Removing that part of the further layer of dry film photoresist which is less chemically robust; and optionally
(j) Repeating steps (g), (h) and (i) with additional layers of dry film photoresist, each sequence of steps repeated after optional step (f).

### DETAILED DESCRIPTION OF THE INVENTION

A first layer of dry film photoresist Tokyo Ohka Kogyo Company Limited TOK 940, which is an acrylic based dry film photoresist with a film thickness of 40 microns, is laminated onto a polystyrene substrate using the Dry Film Photoresist Laminator from

Mega Electronics (Part No: 27-22808-A3) with a laminating temperature of 85° C. and a laminating speed of 3. The surface of the laminated dry film photoresist is selectively radiated through a photo mask (JD Photo) by ultra-violet radiation of 300-460 nm using a Suss MJB4 Mask Aligner (which has a resolution of about 1 micron). The exposed laminated and exposed dry film photoresist is developed in an aqueous 2% Na₂CO₃ solution for about 30 seconds. Fine 75 micron diameter apertures and align marks are now formed in the first layer of laminated and exposed dry film photoresist.

A second layer of dry film photoresist Tokyo Ohka Kogyo Company Limited TOK 940 is then laminated on top of the first layer of laminated and exposed dry film photoresist and exposed to ultra-violet light and aqueous 2% Na₂CO₃ solution in the same manner as described hereinabove. The process was repeated until the combined thickness of the layers of exposed dry film photoresist was 200 microns (ie 5 layers of exposed dry film photoresist) with the aperture size for the fourth and fifth layers being reduced to 50 microns in diameter through utilisation of a different photo mask during these steps.

Then a last layer of dry film photoresist Tokyo Ohka Kogyo Company Limited TOK 920, which is an acrylic based dry film photoresist with a film thickness of 20 microns, was laminated onto the fifth exposed dry film photoresist layer and apertures of 10 microns in diameter created therein using the same technique as disclosed hereinabove with yet another photo mask.

Finally the now finished exposed dry film photoresist structure was peeled off from the polystyrene substrate to become a free-standing film.

The free standing was then affixed to cover the open end of a acrylonitrile butadiene styrene tube using ultrasonic welding in accordance with techniques known in the art.

1. A nozzle for producing a spray, the nozzle comprising a tube and a film, the film being affixed to the tube and covering the bore, wherein the film comprises a plurality of apertures through which a fluid may pass from inside of the tube, and wherein the film comprises a plurality of layers of exposed dry film photoresist.

2. A nozzle according to claim 1, wherein the tube comprises a plastics material.

3. A nozzle according to claim 1, wherein the film is welded to the tube.

4. A nozzle according to claim 3, wherein the film is welded to the tube by using laser welding or ultrasonic welding.

5. A nozzle according to claim 1, wherein the dry film photoresist is a negative photoresist, preferably based on an acrylic or epoxy polymer.

6. A nozzle according to claim 1, wherein the film comprises 2-10, preferably 3-8, most preferably 4-6 layers of exposed dry film photoresist.

7. A nozzle according to claim 1, wherein the apertures have a shortest surface dimension no greater than 20 microns, preferably no greater than 30 microns, most preferably no greater than 50 microns.

8. A nozzle according to claim 1, wherein the apertures have a spacing of at least ten times the shortest surface dimension of the apertures.

9. A dispenser comprising a can which can be pressurised, a valve for regulating the passage of any can contents from the can interior to the can exterior, and a nozzle in accordance with claim 1, wherein the can comprises a can aperture, and the nozzle is arranged to cooperate with the can aperture such that any can contents passing from the can interior to the can exterior pass through the nozzle.

10. A dispenser according to claim 9 wherein the can is pressurised with propellant at 1-10 bar.

11. A method of manufacturing a nozzle in accordance with claim 1, the method comprising in the following order the steps of:
(a) Providing a dry film photoresist;
(a) Laminating the dry film photoresist to a substrate thereby to produce a laminated dry film photoresist;
(b) Selectively exposing parts of the dry film photoresist to ultra-violet radiation or an electron beam thereby to produce exposed dry film photoresist;
(c) Removing that part of the exposed dry film photoresist which is less chemically robust; and either
(d) Delaminating the substrate thereby to produce the film; and then affixing the film to the tube; or
affixing the laminated and exposed dry film photoresist to the tube; and then delaminating the substrate thereby to produce the film now affixed to the tube.

12. A method according to claim 11 wherein the substrate comprises polystyrene.

13. A method according to claim 11 comprising the additional step (f) between steps (d) and (e) of hardening the exposed dry film photoresist using heat, ultra violet light or an electron beam.

14. A method according to claim 11 comprising the additional steps between steps (d) and (e) and after the optional step (f) of:
(g) Laminating a further layer of dry film photoresist to the exposed dry film photoresist; then
(h) Selectively exposing parts of the further layer of dry film photoresist to ultra-violet radiation or an electron beam; then
(i) Removing that part of the further layer of dry film photoresist which is less chemically robust; and optionally
(j) Repeating steps (g), (h) and (i) with additional layers of dry film photoresist, each sequence of steps repeated after optional step (f).
